(19) United States
(12) Patent Application Publication
(10) Pub. No.: US 2026/0343945 A1
(43) Pub. Date: Oct. 29, 2026

(54) THIN-FILM TRANSISTORS WITH CHANNEL-DEPLETING MATERIALS

(71) Applicant: ZINITE CORPORATION, Edmonton (CA)

(72) Inventors: Douglas W. BARLAGE, Edmonton (CA); Viraj BHINGARDIVE, Edmonton (CA)

(21) Appl. No.: 19/547,493

(22) Filed: Feb. 23, 2026

Related U.S. Application Data
(60) Provisional application No. 63/764,269, filed on Feb. 27, 2025.

(51) Int. Cl. H10D 30/67; H10D 30/01

(52) U.S. Cl. CPC H10D 30/6706; H10D 30/031; H10D 30/6755

(57) ABSTRACT

An example thin-film transistor includes a source including a body of source material, a drain, and a body of n-type semiconductor channel material, in which a carrier channel is formed for flow of carriers between the source and the drain when the thin-film transistor is on. The thin-film transistor further includes a body of channel-depleting material in contact with the body of source material and the body of channel material. The channel-depleting material includes a p-type material. The body of channel-depleting material forms a p-n junction and depletion region at the body of n-type semiconductor channel material to reduce the flow of carriers between the source and the drain when the thin-film transistor is off.

### CROSS-REFERENCE TO RELATED APPLICATIONS

This application claims priority to and the benefit of U.S. 63/764,269, filed Feb. 27, 2025, which is incorporated in its entirety herein by reference.

### Field

The present disclosure relates to thin-film transistors and related structures, materials, and methods.

### Background

Thin-film transistors (TFTs) are widely used in display devices and are increasingly used in other applications. A conventional TFT is composed of thin films of materials formed in sequence to create a stack-like arrangement. Such thin films are normally of nanometer-scale thickness.

The manufacture and operation of TFTs are heavily dependent on the materials and processes used. In order to expand the useful applications TFTs, it is helpful to investigate new materials and develop new processes.

### SUMMARY

According to an aspect of the present disclosure, a thin-film transistor includes a source including a body of source material, a drain, and a body of n-type semiconductor channel material, in which a carrier channel is formed for flow of carriers between the source and the drain when the thin-film transistor is on. The thin-film transistor further includes a body of channel-depleting material in contact with the body of source material and the body of channel material. The channel-depleting material includes a p-type material. The body of channel-depleting material forms a p-n junction and depletion region at the body of n-type semiconductor channel material to reduce the flow of carriers between the source and the drain when the thin-film transistor is off.

According to another aspect of the present disclosure, a method of manufacturing a thin-film transistor includes forming a body of channel-depleting material at a substrate, forming a body of source material in contact with the body of channel-depleting material, and forming a body of n-type semiconductor channel material in contact with the body of source material and the body of channel-depleting material. In operation of the thin-film transistor, a carrier channel is formed in the body of n-type semiconductor channel material for flow of carriers when the thin-film transistor is on. The channel-depleting material includes a p-type material and the body of channel-depleting material forms a p-n junction and depletion region at the body of n-type semiconductor channel material to reduce the flow of carriers when the thin-film transistor is off.

In any of the above aspects, any of the following additional features may be used.

The channel-depleting material may include a heavily p-doped conductive material with a narrow bandgap.

The channel-depleting material may include one or a combination of heavily p-doped silicon, heavily p-doped germanium, heavily p-doped silicon-germanium, heavily p-doped germanium-tin, heavily p-doped silicon-tin, heavily p-doped silicon carbide, and a heavily p-doped element of Group 14.

The channel-depleting material may be doped with an acceptor dopant with a concentration of up to about 0.1 atomic %.

The body of channel-depleting material may be a layer that is sufficiently thin to permit sufficient carriers to move through the body of channel-depleting material when the thin-film transistor is on and sufficiently thick to create an effective depletion region to reduce or halt carrier flow through the body of channel material when the thin-film transistor is off.

The body of channel-depleting material may be a layer of thickness less than or equal to about 10 nm.

A second body of channel-depleting material may be formed in contact with the body of drain material and the body of channel material. The second channel-depleting material may include a p-type material and may form a p-n junction and depletion region at the body of n-type semiconductor channel material to reduce the flow of carriers between the source and the drain when the thin-film transistor is off.

### BRIEF DESCRIPTION OF THE FIGURES

FIG. 1 is a cross-sectional view of an example thin-film transistor with channel-depleting material.

FIG. 2 is a cross-sectional view of another example thin-film transistor with channel-depleting material.

FIG. 3 is a cross-sectional view of an example vertical thin-film transistor with channel-depleting material.

FIG. 4 flowchart of an example method of manufacturing a thin-film transistor with channel-depleting material.

### DETAILED DESCRIPTION

The present disclosure provides techniques to reduce off current or leakage current in thin-film transistors. A body of channel-depleting material is provided to the source, and optionally the drain, of a thin-film transistor to create a depletion region in the semiconductor channel material. The depletion region reduces or eliminates off/leakage current when the transistor is off. As such, the thin-film transistor has greater operational efficiency and may be useful in a wider range of applications. At the same time, the thin-film transistor is stackable to form true three-dimensional arrangements.

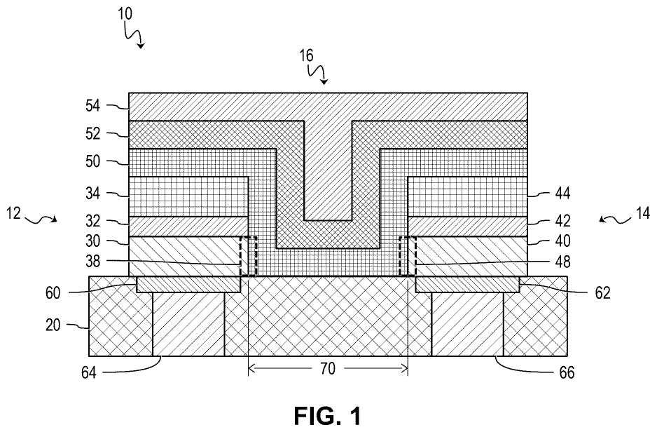

FIG. 1 shows an example thin-film transistor (TFT) 10 according to the present disclosure. The TFT 10 includes a source 12, drain 14, and gate 16. In various examples, TFTs 10 may be manufactured in planar arrangements and/or three-dimensional arrangements using extended front-end-of-line (xFEOL), middle-end-of-line (MEOL), back-end-of-line (BEOL), and/or back-side (BSide) processes. In various examples, the maximum temperature of manufacture of the TFT is limited to about 400° C., so as to allow layers of TFTs to be stacked on each other and/or over a CMOS layer without damaging previously formed active/passive devices, TFTs, and/or wiring.

The TFT 10 is formed with a planar substrate 20. The substrate 20 may be disposed over another layer of TFTs, whether manufactured in accordance with the present disclosure or by another technique, such as CMOS processes.

Examples of materials for the substrate 20 include silicon dioxide; silicon nitride; glass; fluorosilicate glass (FSG); a silicon wafer whose surface is processed with wet thermal oxide (WTO) or similar treatment; carbon doped oxide (CDO); organic polymers such as perfluorocyclobutane or polytetrafluoroethylene; organosilicates such as silsesquioxane, siloxane, organosilicate glass; flexible polymer; plastic; etc. Suitable combinations of such materials may also be used.

The source 12 may be formed of a body of channel-depleting material 30 disposed on the substrate 20 and a body of source material 32 disposed on the body of channel-depleting material 30. Further, a source carrier reservoir 34 may be disposed on the body of source material 32. Each of the bodies of material 30, 32, 34 is in contact with a body of semiconductor channel material 50, which is an n-type material such as tin oxide, that will be discussed in further detail below.

The body of channel-depleting material 30 is disposed on the substrate 20. The body of channel-depleting material 30 may be crystalline, polycrystalline or amorphous. The body of channel-depleting material 30 is a heavily p-doped conductive material with a narrow bandgap. Examples of such materials include heavily p-doped silicon, heavily p-doped germanium, other heavily p-doped elements of Group 14 (aka Group IV), or a combination/alloy of such heavily p-doped elements, such as silicon carbide, silicon-germanium, silicon-tin, germanium-tin. An acceptor dopant, such as boron or other element of Group 13 (aka Group III), may be used. For example, a doping concentration of up to about 0.1 atomic % (e.g., 1 boron atom per 1000 silicon atoms) may be used, and the precise limit may depend on the semiconductor selected. In various examples, heavily doped means as high a degree of doping that is practical and that avoids alloying of the semiconductor and dopant. As the definition of heavily doped depends on factors such as the materials selected and the desired operational characteristics of the TFT, one of ordinary skill in the art, given the benefit of this disclosure and in consideration of such factors, would be able to select a suitable degree of heavy doping.

The body of channel-depleting material 30 may form a p-n junction and depletion region 38 with the n-type channel material 50. The depletion region 38 acts as a conduction barrier to the flow of charge carriers (i.e., electrons) though the channel material 50, thereby reducing the off current (i.e., leakage current) of the TFT 10. This conduction barrier is overcome when the TFT 10 is turned on by applying a voltage to the gate 16, which reduces the depletion region 38 and creates an accumulation layer in the channel material 50 near gate dielectric 52 to allow charge carriers to flow. In this manner, the body of channel-depleting material 30 may serve as a voltage-controlled electron transport barrier, resulting in very low off current through body of channel material 50.

The thickness of the body of channel-depleting material 30 should be selected to obtain a suitable balance: 1) thin enough to provide electrons with a good probability of moving through the body of channel-depleting material 30 when the TFT 10 is on, and 2) thick enough to create an effective depletion region 38 to reduce or halt current flow through the body of channel material 50 when the TFT 10 is off. This balance may be tuned to obtain various levels of on/off current for various implementations. For example, a desired on/off current ratio of, for example, 10¹⁰ may be considered a sufficiently reduced or halted current flow. In this example, the body of channel-depleting material 30 may be formed to a thickness of less than or equal to about 10 nm, such as about 5 nm. In various examples, one of ordinary skill in the art given the benefit of this disclosure would be able to select a suitable thickness for the body of channel-depleting material 30 in consideration of pertinent factors, such as the materials selected and the desired operational characteristics of the TFT 10.

The body of source material 32 may be a metal, such as cobalt, tungsten, ruthenium, molybdenum, or a combination/alloy of such. The body of source material 32 forms ohmic contact with both the body of channel-depleting material 30 and the source carrier reservoir 34, and provides a large supply of charge carriers, in this case electrons. In this example, the source material 30 is formed of ruthenium to a thickness of about 2-10 nm, such as about 5 nm.

The source carrier reservoir 34 is an n-type metal oxide, metal sulfide, or metal selenide. The source carrier reservoir 34 preferably has the same base material as the body of channel material 50 (i.e., doping may be different) and example materials, such as tin oxide, are discussed below. The source carrier reservoir 34 acts as a charge source adjacent the body of source material 32 and channel material 50 to provide a reservoir of negative charge carriers to mitigate carrier starvation.

The source carrier reservoir 34 may be doped with a donor dopant, such as antimony, chlorine, fluorine, or similar dopant, to increase its n-type carrier concentration. Doping with antimony may also reduce contact resistance between the source carrier reservoir 34 and the body of source material 32. Doping increases conductivity and availability of electrons with the tradeoff of reduced mobility. Other potential dopants include other Group 15 (aka Group V) elements, such as phosphorus and arsenic.

In this example, the source carrier reservoir 34 is formed of tin oxide and antimony is used with a concentration is about 1 atomic % or less with respect to tin, with antimony atoms replacing tin atoms. For a gate length of about 100 nm (i.e., defined by gap 70), a suitable doping concentration ranges from about 0.01 atomic % to about 0.1 atomic % or higher, provided that the chemical properties of the channel material 50 are not unduly detrimentally affected. For shorter gate lengths, doping concentration should be increased. For instance, for a 10 nm gate length, a doping concentration of greater than 0.1 atomic % should be used.

In other examples, a dopant such as fluorine or chlorine may be used to replace oxygen in a metal-oxide source carrier reservoir 34. Useful dopant concentrations would vary and one of ordinary skill in the art, given the benefit of this disclosure, would be able to select a suitable concentration for a particular implementation. In still other examples, oxygen vacancies may be induced in the source carrier reservoir 34 to achieve an effect similar to the doping discussed above.

The source carrier reservoir 34 may have a thickness of about 5 -15 nm, such as about 10 nm.

As depicted, the bodies of material 30, 32, 34 are stacked layers, which may be formed by various deposition techniques, as will be discussed in detail below. Each of the bodies of material 30, 32, 34 has an end (side) surface that is in contact with the body of channel material 50.

In various examples, the drain 14 has the same structure as the source 12. That is, the drain 14 may be formed of a body of channel-depleting material 40 disposed on the substrate 20 and a body of drain material 42 disposed on the body of channel-depleting material 40. Further, a drain reservoir 44 may be disposed on the body of drain material 42. Each of the bodies of material 40, 42, 44 has an end (side) surface that is in contact with the body of channel material 50. The body of channel-depleting material 40 may form a p-n junction and depletion region 48 with the n-type channel material 50. For further details of the bodies of material 40, 42, 44 at the drain 14, the corresponding bodies of material 30, 32, 44 at the source 12, discussed above, may be referenced.

In other examples, the drain 14 has structure and/or materials different to the source 12. For example, one or both of the drain-side body of channel-depleting material 40 and drain reservoir 44 is doped to a concentration that is less than the respective source-side channel-depleting material 30 or source carrier reservoir 34. This may increase the gate-drain breakdown voltage. In other examples, the body of channel-depleting material 40 and/or the drain reservoir 44 is omitted.

The source 12 and drain 14 are separated by a gap 70, which contains portions of a body of channel material 50, a body of gate dielectric material 52, and a body of gate material 54.

A body of channel material 50 is disposed between the source 12 and drain 14. In this example, the body of channel material 50 is disposed over the reservoirs 34, 44 and over the substrate 20 between the source 12 and drain 14. The body of channel material 50 is an n-type metal oxide, metal sulfide, or metal selenide semiconductor. Examples of suitable channel materials 50 include tin oxide, zinc oxide, titanium oxide, tungsten oxide, indium gallium zinc oxide (IGZO), indium tin oxide (ITO), and indium tungsten oxide (IWO).

In this example, the body of channel material 50 is a layer of tin oxide, which is primarily or entirely tin (IV) oxide (SnO₂), with a thickness of about 5 nm to about 10 nm. In this example, the layer of tin oxide is about 7 nm thick.

When tin oxide is used as the body of channel material 50, it may be generally polycrystalline with a preferred crystallite orientation of Miller index <110>, as determined using grazing-incidence x-ray diffraction (GI-XRD) with ω=0.5° on 20 nm and/or 40 nm thick samples. Polycrystalline tin oxide with this preferred crystal orientation provides good carrier mobility and good stability, which improves the performance and useful life of the TFT 10.

For sake of clarity, tin oxide with an orientation of <110> means that one of the directions in the family of directions <110>, such as direction [110], is substantially normal to the plane of the substrate 20. In other words, a plane of the family {110}, such as the plane (110), is substantially parallel to the plane of the substrate 20.

In such examples, the crystallinity of the thin film of tin oxide is preferably at least about 80%, more preferably at least about 85%, more preferably at least about 90%, and still more preferably at least about 95%. Regions outside the 2θ angular range of 20-60° may be ignored when computing crystallinity.

It is important to note that GI-XRD measurements may be performed on thicker samples of tin oxide (e.g., 20 nm or 40 nm) to provide sufficient accuracy, as the GI-XRD technique is known to lose accuracy as film thickness decreases. While 20 nm and 40 nm are considerably thicker than the example thicknesses of the body of channel material 50 discussed above, GI-XRD may still be used to establish useful process parameters. Forming process parameters may be established by having a thicker film, such as 20 nm or 40 nm, take the preferred crystal orientation. A thinner film, such as 7 nm, may then be deposited using these established process parameters. If the thinner film performs sufficiently well, then the process parameters are useful. While it is contemplated that the thinner film will have the same or similar crystal orientation as the thicker film, this need not be confirmed with measurement.

In some examples, the body of channel material 50 is not doped. In other examples, the body of channel material is doped with a donor dopant, such as the examples discussed above with regard to the source carrier reservoir 34. When such a dopant is used, its concentration should be less than the dopant concentration of the source carrier reservoir 34. When the channel material 50 is tin oxide doped with antimony, an example range of suitable dopant concentrations is about 3 ppb (3×10⁻⁷ atomic %) to about 4 ppm (3×10⁻⁴ atomic %), where such concentrations are with respect to tin atoms.

The body of gate dielectric material 52 is disposed over the body of channel material 50. Examples of gate dielectric materials include high-κ dielectric materials, hafnium oxide, silicon dioxide, silicon nitride, zirconium oxide, and aluminum oxide. In this example, the body of gate dielectric material 52 is a layer of hafnium oxide about 10-15 nm thick, such as about 12.5 nm thick.

The TFT 10 further includes a body of gate material 54 (also termed “gate metal”) disposed over the gate dielectric material 52. The gate material is a conductor. Examples of gate materials include cobalt, tungsten, ruthenium, molybdenum, or a combination/alloy of such. In this example, the body of gate material 54 is about 20-40 nm thick, such as about 30 nm thick.

The body of channel material 50, body of gate dielectric material 52, and body of gate material 54 are formed in sequence over the raised pillar-like source 12 and drain 14 and within the trench or gap 70 between the source 12 and drain 14, so that each body 50, 52, 54 conforms to the contour of the underlying material.

The TFT 10 further includes a source contact 60 connected to the channel-depleting material 30 of the source 12 and a drain contact 62 connected to the channel-depleting material 40 of the drain 14. The source contact 60 provides an electrical connection with the channel-depleting material 30 to conduct current to/from the source 12. Likewise, the drain contact 62 provides an electrical connection with the channel-depleting material 40 to conduct current to/from the drain 14. Examples of materials for contacts 60, 62 include cobalt, tungsten, ruthenium, molybdenum, or a combination/alloy of such. Each contact 60, 62 may be connected to a respective via 64, 66 that extends through the substrate 20 to provide for source/drain electrical connections.

In operation, when a voltage is applied across the source contact 60 and drain contact 62, and when a suitable voltage is applied to the body of gate material 54, a carrier channel forms in the body of channel material 50, which causes flow of current between source 12 and drain 14. When the voltage is removed, the flow of current is reduced to a very low amount, as facilitated by the depletion region 38 caused by the channel-depleting material 30 at the source 12 and, if used, by the depletion region 48 caused by the channel-depleting material 40 at the drain 14.

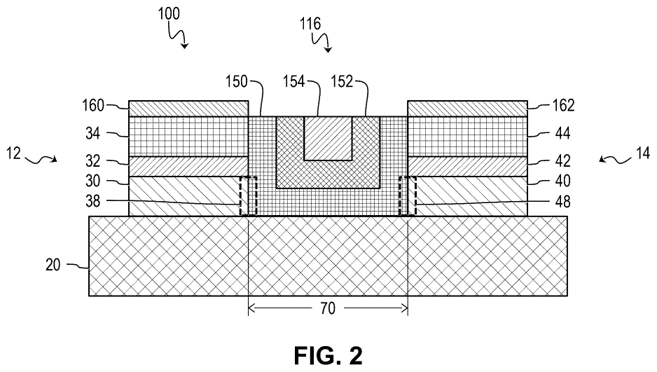

FIG. 2 shows another example TFT 100 according to the present disclosure. The TFT 100 is similar to the TFT 10 and only differences will be discussed in detail. The discussion of the TFT 10 may be referenced for further description. The TFT 100 includes a source 12, drain 14, and gate 116 with contacts on the same side (i.e., the top in the orientation depicted).

The source 12 and drain 14 include the respective bodies of material 30, 32, 34, 40, 42, 44, as discussed above, and which provide substantially the same utility as in the TFT 10.

The TFT 100 includes top source/drain contacts 160, 162 instead of the bottom source/drain contacts 60, 62 of the TFT 10. To facilitate placement of the contacts 160, 162, a body of channel material 150, a body of gate dielectric material 152, and a body of gate material 154 omit material above the source 12 and drain 14 as used in the TFT 10. Rather, material for the bodies 150, 152, 154 is limited to being within the gap 70 between the source 12 and drain 14. This may be achieved by, for example, forming bodies 50, 52, 54, as shown in FIG. 1, and then planarizing (e.g., chemical-mechanical polishing or CMP) the bodies 50, 52, 54 down to the reservoir material 34, 44. This results in the U-shaped bodies of channel and dielectric material 150, 152 and the plug-like body of gate material 154. Each source/drain contact 160, 162 may then be formed over the respective reservoir 34, 44. The source/drain contacts 160, 162 may be formed of metal, such as those given above for the source/drain contacts 60, 62.

Interlayer dielectric (ILD) may be disposed over the source/drain contacts 160, 162, and vias may be provided to electrically connect the source/drain contacts 160, 162. In other examples, the source/drain contacts 160, 162 are vias. Planarizing and using ILD in this manner allows TFT 100 to be readily stackable in 3D arrangements.

In other examples, features and aspects of the TFTs 20, 100 are combined. For example, in one example, a top contact 160 (FIG. 2) is used for the source and a bottom contact 62 (FIG. 1) is used for the drain. In another example, a bottom contact 60 (FIG. 1) is used for the source and a top contact 162 (FIG. 2) is used for the drain.

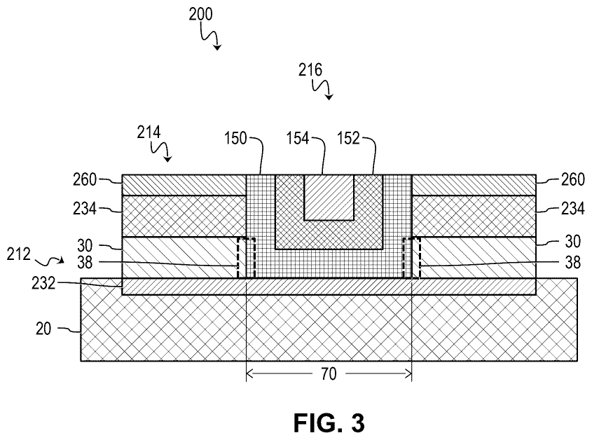

FIG. 3 shows another example TFT 200 according to the present disclosure. The TFT 200 is similar to the TFTs 10, 100 and only differences will be discussed in detail. The discussion of the TFTs 10, 100 may be referenced for further description. The TFT 200 includes a source 212, drain 214, and gate 216, where the drain 214 is above the source 212 (in the orientation depicted). The TFT 200 may be referred to as vertical.

The source 212 includes a body of source material 232 is formed at a substrate 20. The body of source material 232 may be formed within a recess in the substrate 20, as depicted, or may be formed on the main surface of the substrate 20. The discussion above for the body of source material 32 may be referenced for suitable materials, thickness, etc. for the body of source material 232.

The source 212 further includes bodies of channel-depleting material 30 formed on the body of source material 232. The bodies of channel-depleting material 30 are separated by a gap 70, within which are formed a body of channel material 150, a body of gate dielectric material 152, and a body of gate material 154, whose composition and function are substantially the same as discussed above. The description above may be referenced for details concerning each of the bodies of channel-depleting material 30. Note that the bodies of channel-depleting material 30 may, in various examples, actually be one body of channel-depleting material 30 that appears as two bodies in the cross-section depicted.

Bodies of interlayer material 234 are formed on both sides of the gap 70 over the bodies of channel-depleting material 30. The interlayer material 234 is an insulator, such as silicon dioxide, that prevents shorting between source 212 and drain 214. Note that the bodies of interlayer material 234 may, in various examples, actually be one body of interlayer material 234 that appears as two bodies in the cross-section depicted.

The drain includes drain contacts 260 formed on both sides of the gap 70 over the bodies of interlayer material 234 The discussion above for the body of drain material 42 may be referenced for other details, such as suitable materials, thickness, etc. Note that the drain contacts 260 may, in various examples, actually be one drain contact 260 that appears as two in the cross-section depicted.

The TFTs 10, 100, 200 may be manufactured using xFEOL, FEOL, MOL, BEOL, BSide or a combination of such. A manufacturing process may include forming one or more layers of TFTs 10, 100, 200 over other devices made using xFEOL, FEOL, MOL, BEOL, any/or BSide processes.

The manufacture of materials, layers, and/or features of semiconductor devices is referred to herein as “forming.” As will be apparent to those of ordinary skill in the art, unless otherwise mentioned, “forming” is intended to include all semiconductor manufacturing techniques suitable and applicable therefor including, without limitation, deposition (e.g., chemical vapor deposition or CVD, atomic layer deposition or ALD, physical vapor deposition or PVD, etc.), plasma-enhanced/assisted atomic layer deposition (PEALD/PAALD), thermal ALD (T-ALD), plasma-enhanced chemical vapor deposition (PECVD), sputtering, lithography/photolithography, etching, implantation, annealing, oxidation, and similar processes. While examples of specific types of forming are given below, it should be understood that comparable methods of forming may be alternatively or additionally used, unless otherwise mentioned, without departing from the present disclosure.

During manufacture, the TFT 10 in its partially or fully complete state may be subject to high temperatures and/or environments/materials that contain hydrogen, such as a forming gas (i.e., nitrogen and hydrogen) anneal, as may be required for various reasons, such as to stabilize material or to support the forming of material of the TFT 10 or other materials, components, or devices that are formed before or after the TFT 10 is formed. For example, the forming of ILD may involve forming gas anneal, the use of silane (SiH₄) may introduce hydrogen, etc.

Any suitable number and configuration of forming gas anneals may be performed. Annealing may be done at about 400° C. for about 120 minutes, for example, or longer (e.g., 3 or 4 hours). Higher temperatures and longer times are possible.

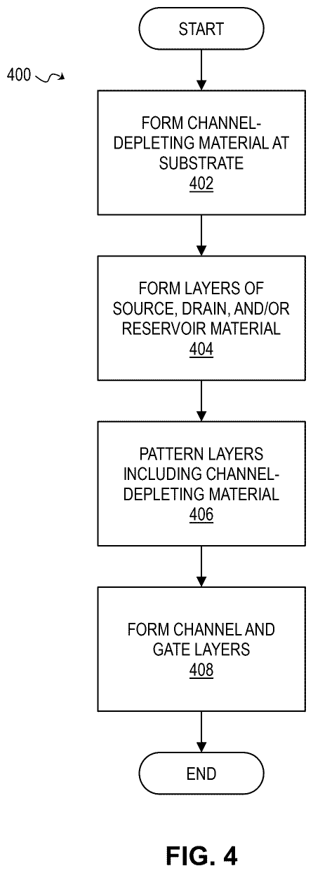

With reference to example method 400 of FIG. 4 and the example TFT 10 of FIG. 1, manufacture of the TFT 10 will now be described.

A substrate 20 may be provided or formed as discussed above.

At block 402, a layer of channel-depleting material, such as heavily p-doped silicon or other material described above, is formed at the substrate 20. In this example, the layer of channel-depleting material is formed over and in contact with the substrate 20. The layer of channel-depleting material may be formed by ALD or other deposition process.

At block 404 additional layers of material are stacked over the layer of channel-depleting material. A layer of source/drain material, such as ruthenium, is formed over the layer of channel-depleting material. The source/drain material may be formed by sputtering to a desired thickness. A layer of reservoir material, such as tin oxide, is formed over the layer of source/drain material. The layer of reservoir material may be formed by ALD or other deposition process.

At block 406, the layers formed at blocks 402,404 are patterned to form the bodies of channel-depleting material 30, 40, source and drain material 32, 42, and reservoir material 34, 44 and to define a gap 70 therebetween. Lithography and etching, such as inductively coupled plasma reactive ion etching (ICP-RIE), may be used for such patterning.

The layer of channel-depleting material, source/drain material, and reservoir material may be patterned individually in separate lithography and etching processes or two or more of such layers may be patterned together. In one example, the reservoir material is patterned using lithography and etching processes, and then the resulting bodies of reservoir material 34, 44 are used as a hardmask to etch the channel-depleting material and source/drain material.

Subsequently, at block 408, layers of channel material 50, gate dielectric material 52, and gate metal 54 are formed in sequence over the source/drain pillars formed and within the gap 70.

The layer of channel material 50, e.g., tin oxide, may be formed by PEALD with oxygen plasma, T-ALD, or similar technique. Annealing may be useful to develop and/or maintain the preferred crystallite orientation of the channel material 50. Annealing may be performed immediately after deposition of the layer of channel material 50 or at a later stage. Example anneal conditions are 400° C. for 120 minutes with forming gas.

The layer of gate dielectric material 52 may be formed by PEALD, T-ALD, etc.

The layer of gate material 54 may be formed by sputtering.

Further forming may be performed, such as annealing, as may be required for the particular application of the TFT 10.

Thus, the TFT 10 of the structure shown in FIG. 1 is formed.

Regarding manufacture of the TFT 100 of FIG. 2, the same general process discussed above may be used with some notable differences. Layers of channel material 50, gate dielectric material 52, and gate material 54 may be formed as described above and then planarized (e.g., polished) down to obtain the bodies 150, 152, 154 shown in FIG. 2. The same applies to the making of the TFT 200 of FIG. 3. Planarization allows TFTs to be stacked among layers of ILD and connecting wiring. Further regarding the TFT 200, the substrate 20 may first be patterned to form a recess to receive the body of source material 232.

In view of the above, it should be apparent that a body of depleting material may be used in a TFT to form a depletion region in semiconductor channel material to reduce or eliminate off/leakage current when the TFT is off. This may increase operational efficiency of the TFT and may allow such TFTs to be useful in a wider range of applications. The TFT may also be stackable to form true three-dimensional arrangements of TFTs and/or other devices.

Auxiliary verbs “can” and “may” are used interchangeably herein to denote components, features, and/or aspects of the present invention that are capable, configurable, selectable, modifiable, or optional, as would be apparent to one of ordinary skill in the art given the benefit of this disclosure. These terms should not be taken as limiting the present invention, unless otherwise specified.

Spatial prepositions, such as “over”, “under”, “above”, “below”, “up”, “down”, “beside”, etc., are provided for sake of explanation and should not be taken as limiting the present invention to an absolute spatial orientation or arrangement, unless otherwise specified. For example, one of ordinary skill in the art would understand that a first element is above or below a second element depending on the perspective of the observer.

The articles “a”, “an”, “the”, “said”, etc. indicate singular and plural, unless otherwise specified.

The conjunction “or” is used inclusively and should be understood to mean “and/or”, unless otherwise specified.

Sets of elements A, B, C described as A, B, or C; A, B, and C; A, B, and/or C; or A, B, C should be considered open sets from which one or more elements or a combination of one or more elements may be selected, unless otherwise specified. Sets of elements are open, unless specified to be closed, for example, by use of the term “consist”, “consisting”, or similar closed language.

The above clarifications apply to both the specification and claims.

The figures are not to scale, unless otherwise specified.

The above-described embodiments are intended to be examples of the present invention and alterations and modifications may be effected thereto, by those of ordinary skill in the art, without departing from the scope of the invention which is defined solely by the claims appended hereto.

1. A thin-film transistor comprising:
a source including a body of source material;
a drain;
a body of n-type semiconductor channel material, in which a carrier channel is formed for flow of carriers between the source and the drain when the thin-film transistor is on;
a body of channel-depleting material in contact with the body of source material and the body of channel material;
wherein the channel-depleting material includes a p-type material; and
wherein the body of channel-depleting material forms a p-n junction and depletion region at the body of n-type semiconductor channel material to reduce the flow of carriers between the source and the drain when the thin-film transistor is off.

2. The thin-film transistor of claim 1, wherein the channel-depleting material includes a heavily p-doped conductive material with a narrow bandgap.

3. The thin-film transistor of claim 1, wherein the channel-depleting material includes one or a combination of heavily p-doped silicon, heavily p-doped germanium, heavily p-doped silicon-germanium, heavily p-doped germanium-tin, heavily p-doped silicon-tin, heavily p-doped silicon carbide, and a heavily p-doped element of Group 14.

4. The thin-film transistor of claim 1, wherein the channel-depleting material is doped with an acceptor dopant with a concentration of up to about 0.1 atomic %.

5. The thin-film transistor of claim 1, wherein the body of channel-depleting material is a layer that is:
sufficiently thin to permit sufficient carriers to move through the body of channel-depleting material when the thin-film transistor is on; and
sufficiently thick to create an effective depletion region to reduce or halt carrier flow through the body of channel material when the thin-film transistor is off.

6. The thin-film transistor of claim 1, wherein the body of channel-depleting material is a layer of thickness less than or equal to about 10 nm.

7. The thin-film transistor of claim 1, wherein the drain includes a body of drain material, the thin-film transistor further comprising:
a second body of channel-depleting material in contact with the body of drain material and the body of channel material;
wherein the second channel-depleting material includes a p-type material; and
wherein the second body of channel-depleting material forms a p-n junction and depletion region at the body of n-type semiconductor channel material to reduce the flow of carriers between the source and the drain when the thin-film transistor is off.

8. A method of manufacturing a thin-film transistor, the method comprising:
forming a body of channel-depleting material at a substrate;
forming a body of source material in contact with the body of channel-depleting material; and
forming a body of n-type semiconductor channel material in contact with the body of source material and the body of channel-depleting material, wherein, in operation of the thin-film transistor, a carrier channel is formed in the body of n-type semiconductor channel material for flow of carriers when the thin-film transistor is on;
wherein the channel-depleting material includes a p-type material and the body of channel-depleting material forms a p-n junction and depletion region at the body of n-type semiconductor channel material to reduce the flow of carriers when the thin-film transistor is off.

9. The method of claim 8, wherein the channel-depleting material includes a heavily p-doped conductive material with a narrow bandgap.

10. The method of claim 8, wherein the channel-depleting material includes one or a combination of heavily p-doped silicon, heavily p-doped germanium, heavily p-doped silicon-germanium, heavily p-doped germanium-tin, heavily p-doped silicon-tin, heavily p-doped silicon carbide, and a heavily p-doped element of Group 14.

11. The method of claim 8, wherein the channel-depleting material is doped with an acceptor dopant with a concentration of up to about 0.1 atomic %.

12. The method of claim 8, wherein the body of channel-depleting material is formed as a layer to a thickness that is:
sufficiently thin to permit sufficient carriers to move through the body of channel-depleting material when the thin-film transistor is on; and
sufficiently thick to create an effective depletion region to reduce or halt carrier flow through the body of channel material when the thin-film transistor is off.

13. The method of claim 8, wherein the body of channel-depleting material is a layer of thickness less than or equal to about 10 nm.

14. The method of claim 8, further comprising:
forming a second body of channel-depleting material;
forming a body of drain material in contact with the second body of channel-depleting material; and
forming the body of n-type semiconductor channel material in contact with the body of drain material and the second body of channel-depleting material;
wherein the second channel-depleting material includes a p-type material and the second body of channel-depleting material forms a p-n junction and depletion region at the body of n-type semiconductor channel material.
